(19) United States
(12) Patent Application Publication
(10) Pub. No.: US 2005/0151243 A1
(43) Pub. Date: Jul. 14, 2005

(54) Semiconductor chip heat transfer

(76) Inventor: Lawrence Shungwei Mok, Brewster, NY (US)

Correspondence Address: Alvin J. Riddles, Candlewood Isle, Box 34, New Fairfield, CT, 06812, US

(21) Appl. No.: 10/755,589

(22) Filed: Jan. 12, 2004

(51) Int. Cl. H01L 23/10; H01L 21/48

(52) U.S. Cl. 257/707; 257/713; 438/122

(57) ABSTRACT

In accordance with the invention a chip packaging structure and technique is arranged in which multiple surfaces of the semiconductor chip are surrounded in a pocket in a module with direct transfer thermally conductive materials. The chip packaging module consists of a thermally conductive plate and cover which together form a thermally conductive pocket or shell around the chip. The pocket inside the shell is filled with thermally conductive paste-like materials which are compressed under spring forces. The direct thermal transfer is achieved using thermal transfer plates of such materials such as silicon, diamond-like, or copper-invar-copper plates on all six sides.

### FIELD OF THE INVENTION

The invention is directed to the transfer of heat generated in a semiconductor chip out of the vicinity of that chip and in particular to the transfer of heat generated in the body of a chip through the several surfaces of the chip body.

### BACKGROUND OF THE INVENTION

It is well known that the power and power density of semiconductor chips are increasing rapidly. Chips generally have essentially parallel broad area surfaces separated by side surfaces of the thickness dimension. Heat is generated in the chip close to the active broad area surface on which most of the semiconductor circuitry is built and through which external connections are made, and that heat is removed from the heat radiating broad area surface or back side of the chip. At the current state of the art the heat generated on the active side of the chip has to pass through body of the chip itself to the heat radiating broad area surface, the chip-to-package interface, the package cover, and then to a heat sinking device. The chip is joined at the active or external connection broad area surface, to the chip packaging substrate, through signal and power connections which are usually solder ball interconnections. Very little heat will go to the chip packaging substrate through the signal and power type solder ball interconnections. Such a single and long heat transfer path as is currently used is just not efficient enough for cooling and is limiting increases in performance. A need is developing in the art for chip packaging that has better heat transfer.

### SUMMARY OF THE INVENTION

In accordance with the invention a chip packaging structure and technique is arranged wherein the chip is in a pocket on a thermally conductive member covered by a thermally conductive cover in which multiple surfaces of the semiconductor chip can be surrounded with direct transfer thermally conductive materials. The direct thermal transfer is achieved using thermal transfer plates of such as silicon, diamond-like, or copper-invar-copper plates on all six sides. The plate in contact with the active external connection broad area chip surface will have through vias coinciding with the signal and power connection pads of the chip, the chip is bonded on those vias on one side of the plate, and is in turn soldered on the substrate of the chip package. The pocket or cavity the chip is in, is filled with thermally conductive paste-like materials such as silicon nitride powder in an oil mixture. Heat generated from the chip in this structure can, therefore, be directly transferred to those thermally conductive plates in all directions through all six surfaces. Heat is not restricted to flow in only one direction.

### BRIEF DESCRIPTION OF THE DRAWINGS

FIG. 1 is a cutaway view of the chip packaging of the invention illustrating highly thermally efficient direct thermal transfer members wrapped around all surfaces of the chip.

FIGS. 2 and 3 are each a cross-sectional view of the chip packaging of the invention illustrating, in FIG. 2 the use of solder balls and in FIG. 3 the use of thermo compression bonding respectively for connections through the active external connection broad area chip surface.

FIG. 4 is a cross-sectional view of the chip packaging of the invention illustrating, using insert members such as copper-invar-copper for the heat conduction plates.

FIG. 5 is an enlarged cross-sectional view of the chip packaging of the invention having transmission-line type of vias in the conduction plates and thermally conductive underfills between the chip and the heat conduction plate.

FIG. 6 is a cross-sectional view of the chip packaging of the invention illustrating wire bonding to the side of the chip away from the substrate, and,

FIG. 7 is a cross-sectional view of the chip packaging of the invention illustrating a modification of the heat sinking device to form the pocket surrounding the chip.

### DESCRIPTION OF THE INVENTION

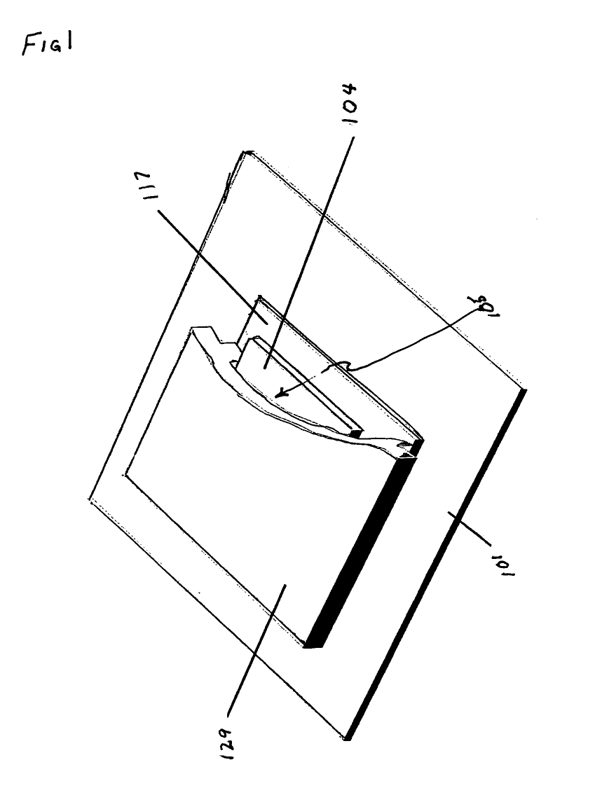

FIG. 1 is a cutaway view of the chip packaging of the invention illustrating highly thermally efficient direct thermal transfer to plates positioned around all surfaces of the chip. Referring to FIG. 1 where only the major components are illustrated, the semiconductor chip is labelled element 104 and it is bonded on the active external connection broad area chip surface thereby to a heat conduction plate 117 with signal and power connection pads of the chip. The heat conduction plate 117 together with a heat conduction cover 129 are shaped to form a recess pocket. The cover 129, attached on the outside to an external heat sinking means not shown, at the periphery, is soldered on the heat-conduction plate 117. The semiconductor chip 104 is, therefore, in the pocket 105 and surrounded by the pocket walls of the cover. The heat conduction plate 117 has the signal and power connection pads not shown in this view which are mounted on the chip packaging substrate 101.

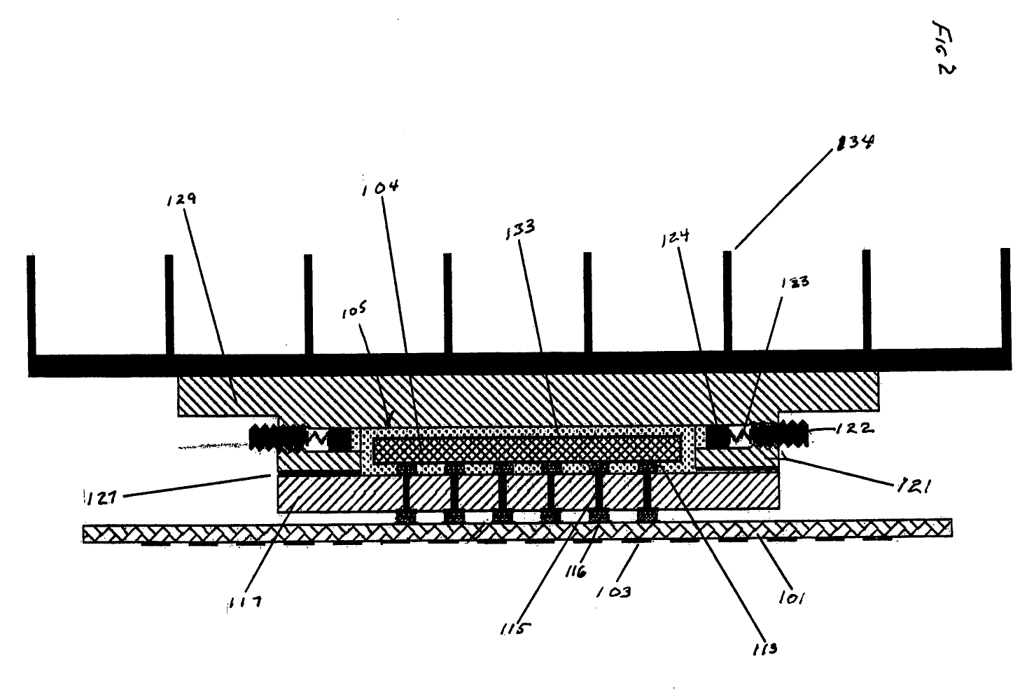

FIG. 2 is a cross-sectional view of the improved heat-transfer technique chip package of the invention. Referring to FIG. 2 wherein like reference numerals are assigned to like components, the semiconductor chips 104 are bonded to the heat conduction plate 117 using solder balls 113 which contact the metal filaments in the vias 115 that extend through in the heat conduction plate 117. The remaining contacts 116 of the vias through the heat conduction plate 117 are then soldered to the chip packaging substrate 101 by the solder ball interconnection technology. There are multiple metal layers either on the top of or embedded inside the packaging substrate 101 to fan out the signal and power connections to the other side of the substrate 101. These metal layers are not shown in the figure and are to be terminated at the connection pads 103 on the other side of the substrate 101. The heat conduction cover 129 that has a recess pocket corresponding to 105 in FIG. 1 centered on the side next to the chip, is soldered to the heat conduction plate 117 at the peripheral area 127. There are several fill ports 121 at the side walls of the pocket 105 of the heat conduction cover 129. The fill ports 121 are used to fill the empty space inside the pocket 105 with thermally conductive paste-like materials 133. Once the space is fully filled, all of the fill ports will be sealed by a set-screw type of plug which consists of three components: a stopper 124, a spring 123, and a set screw 122. The stopper 124 is free to move along the inner walls of the fill ports and is used to compress the thermally conductive paste-like materials under the spring 123. The set screw 122 is used to adjust the compression force. In this arrangement, the thermally conductive paste-like materials can expand and contract freely inside the pocket 105 around the semiconductor chip 104. A heat sinking device 134 such as a finned air-cooled radiating element is glued or mounted on the top surface of the heat conduction cover 129 with a good thermal contact. Heat generated in the active circuitry on the surface at the solder balls 113 side of the semiconductor chip 104 can now flow through the thermally conductive paste-like materials, the heat conduction plate 117 and cover 129, and then to the heat sinking device 134 from all six surfaces of the chip 104.

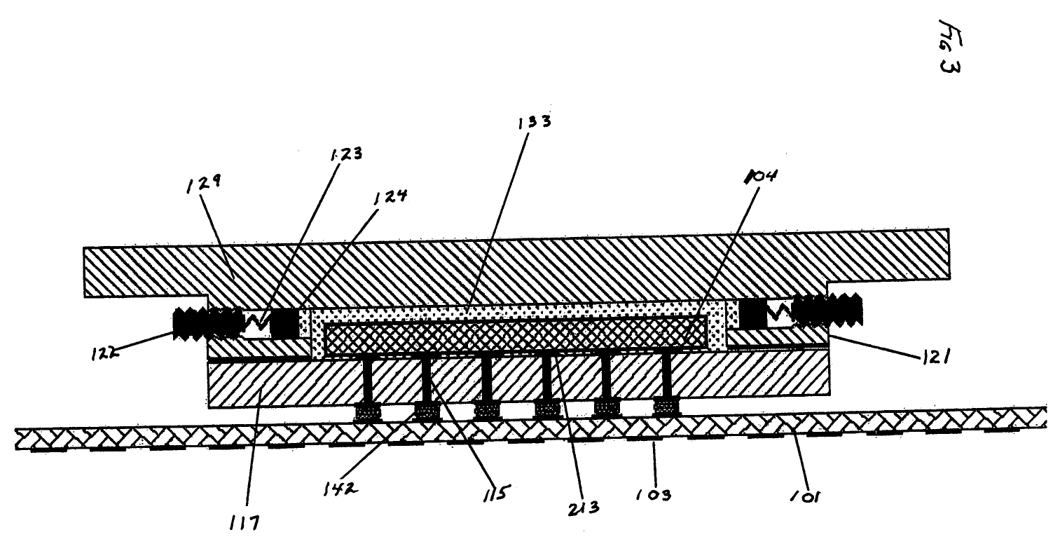

There are several variations of the structural principle where other standard in the art technologies are employed. In FIG. 3 the thermocompression bonding technology is illustrated.

Referring to FIG. 3, the semiconductor chip 104 is bonded to the heat conduction plate 117 using a thermocompression technique. In this technique, there is a metal bump 213 as each of the connection pads, of which six are shown, on the chip 104. The pad bumps 213 are bonded to the metal filament member of the vias 115 in the heat conduction plate 117 by the thermocompression bonding technology known in the industry. All other elements are as described in FIG. 2.

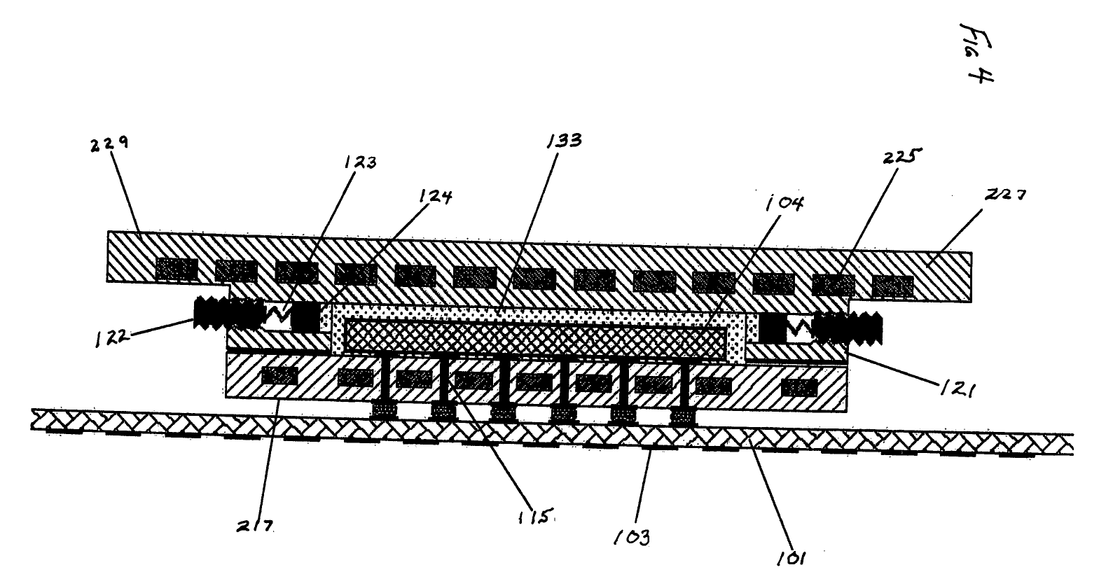

Heavy heat transfer is achieved through the use of inserted heat transfer members in the conduction plates at the faces of the chip. This is illustrated in connection with FIG. 4 which shows the use of a material such as copper with invar inserts as materials for the heat conduction cover and plates. Referring to FIG. 4, which is a cross section, an invar core mesh 225 has copper 227 through the perforations and over both sides of the invar core 225 through the use of hot rolling processes standard in the industry, thus providing the heat conduction cover member labelled element 229. A similar structural approach is used for construction of the heat conduction plate 217 is also made by the same type of structure as the heat conduction cover 229 with the vias 115 being placed between the core 225 portions. All other elements serve the purposes described in the earlier figures.

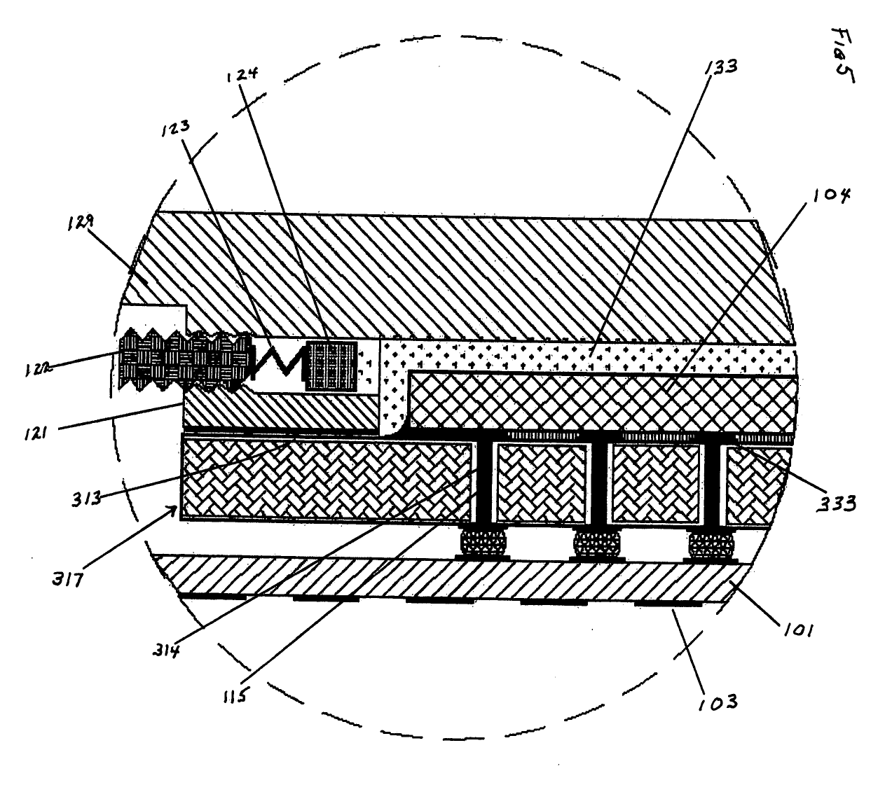

The heavy heat transfer through inserted members in the conduction plates on the chip faces concept is continued in the packaging illustrated in connection with FIG. 5. Referring to FIG. 5 an enlarged, cross-sectional view is shown of an improved chip package with the gap between the semiconductor chip 104 and the heat conduction plate 317 filled with thermally conductive polymeric materials 333 to enhance the heat transfer between the chip 104 and the plate 317. In this figure, the vias 115 in the heat conduction plate 317 are constructed like a coaxial transmission cable in which the vias 115 are surrounded with a layer of dielectric materials 314 such as polyimide. The dielectric layer 314 is then surrounded by a metal core 313 which is connected to the ground potential of the chip package. In this arrangement, the electrical signals passing through the vias 115 will be well behaved and protected like passing through coaxial cables. All other elements serve the purposes described in the earlier figures.

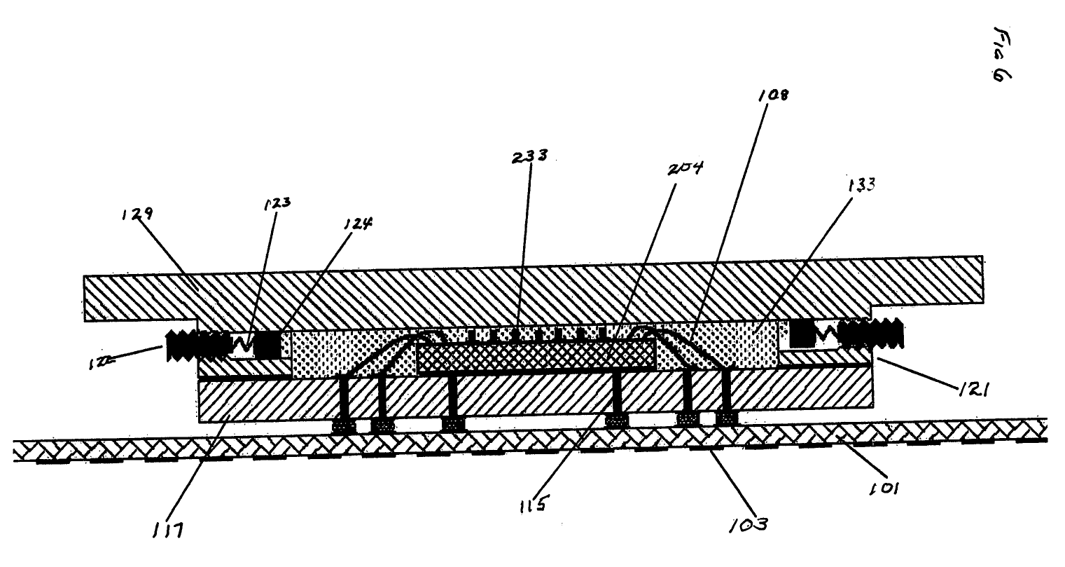

The structure of the invention will accommodate attachment of conductors to the heat radiating side of the chip away from the substrate. Referring to FIG. 6 there is shown a cross-sectional view of the chip package of the invention in which the wire bond connected chip 204 is mounted on the heat conduction plate 117 by die attachment materials such as epoxies or solders. With this structure it becomes possible to employ wires 108 that can connect the chip signal and power pads directly to the vias on the heat conduction plate 117. The space on and around the chip 204 is filled with thermally conductive paste 133 using the fill ports on the cover 129. There are optional metal studs 233 which are soldered on the surface of the chip 204 to enhance heat transfer from the chip to the thermally conductive paste 133.

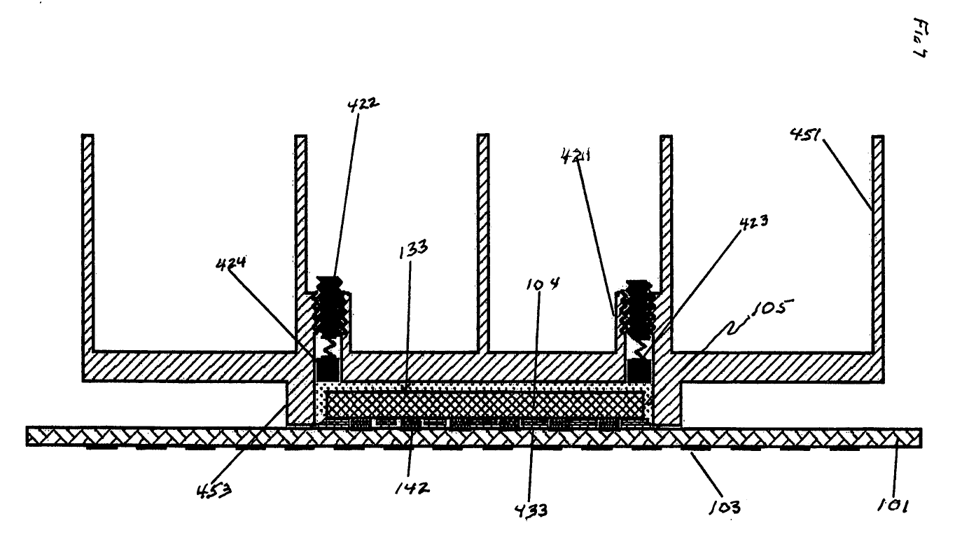

FIG. 7 is a cross-sectional view of the chip packaging of the invention illustrating further modification of the pocket concept for increased heat conduction. Referring to FIG. 7 a modified base of the heat sinking device serves to form the pocket 105 of FIG. 1. In this arrangement, the pocket 105 is formed by protrusion walls 453 at the bottom surface of the base of the heat sinking device 451. The heat sinking device 451 is compressed down to the chip packaging substrate 101 until the head of the walls 453 are in contact with the top surface of the substrate 101 near the perimeter area. The thermally conductive materials 433 are used to fill the gap between the chip 104 and the substrate 101. The substrate 101 also can be made of thermally conductive materals.

There are several fill ports 421 at the base of the heat sinking device 451. Each fill port 421 is equipped with set screw 422, spring 423, and stopper 424. Once the heat sinking device 451 is compressed down on the substrate 101, a sealed pocket 105 space is formed on and around the chip 104 within the pocket in the base of the heat sinking device 451. This space is then filled with thermally conductive paste 133.

What has been described is a structure and method of packaging a semiconductor chip to provide improved heat transfer. The packaging consists of arranging a thermally conductive plate and cover that form a thermally conductive pocket shell around the chip so that heat can be extracted from all sides of the chip into a thermoconductive paste type material surrounding ethe chip in the pocket.

1. A chip package for the transfer of heat generated in a semiconductor chip away from said semiconductor chip,
comprising in combination:
a thermally conductive plate having first and second broad area surfaces, said plate being positioned with said first surface on a conductor bearing substrate, said thermally conductive plate having at least one of power and signal type conductor connecting members extending through said plate,
a semiconductor chip body with a first, power and signal input broad area surface and a second, heat radiating broad area surface separated by side surfaces, said chip body being positioned on said thermally conductive plate with said first power and signal input broad area surface in contact with said first broad area surface of said thermally conductive plate, and,
a thermally conductive cover member extending over said chip and enclosing said chip in a cavity with the edges of said cover surrounding said chip and being in continuous contact with said second surface of said thermally conductive plate.

2. The chip package of claim 1 including a heat sinking device thermally conductively attached to the outside of said thermally conductive cover.

3. The chip package of claim 2 wherein said cavity is filled with a thermally conductive paste material.

4. The chip package of claim 3 wherein said power and signal type conductor connecting members extending through said thermally conductive plate have termination portions at each of said first and second broad area surfaces of said thermally conductive plate and a connecting filamentary portion extending through said thermally conductive plate and electrically joining said termination portions.

5. The chip package of claim 4 wherein said termination portions of said connecting members at least at the interface between said first, power and signal input broad area surface of said chip and said first broad area surface of said thermally conductive plate operate to position said first power and signal input broad area surface of said chip at a separation distance from said first broad area surface of said thermally conductive plate.

6. The chip package of claim 5 wherein said cavity is filled with a thermally conductive paste material, said thermally conductive past material extending into said interface between said first, power and signal input broad area surface of said chip and said first broad area surface of said thermally conductive plate surrounding all conductor connections at said interface.

7. The chip package of claim 6 wherein said thermally conductive paste material in said cavity is under pressure.

8. The chip package of claim 7 wherein said pressure on said thermally conductive paste in said cavity is achieved through at least one input port into said cavity with a spring loaded stopper.

9. The chip package of claim 8 including a heat sinking device thermally conductively attached to the outside of said thermally conductive cover.

10. A chip package for the transfer of heat generated in a semiconductor chip away from said semiconductor chip,
comprising in combination:
a thermally conductive plate having first and second broad area surfaces, said plate being positioned with a first surface on a power and signal conductor bearing substrate, said thermally conductive plate further having at least one of power and signal conveying conductor connecting members extending through said plate,
a semiconductor chip body with a first, active power and signal input broad area surface and a second, heat radiating broad area surface separated by side surfaces, said chip body being positioned on said thermally conductive plate with said first active power and signal input broad area surface in contact with said first broad area surface of said thermally conductive plate,
a thermally conductive cover member, externally attached to heat sinking means, encompassing a cavity containing said chip and having the peripheral edges thereof in continuous contact with said second surface of said thermally conductive plate, and,
a quantity of thermally conductive paste filling said cavity.

12. The chip package of claim 11 including a heat sinking device thermally conductively attached to the outside of said thermally conductive cover.

13. The chip transfer package of claim 12 wherein at least one of said thermally conductive plate and said thermally conductive cover are a material taken from the group of silicon, diamond like coated material and copper-invar-copper material.

14. The chip transfer package of claim 13 wherein said thermally conductive paste is silicon nitride powder in an oil mixture.

15. In the packaging of a semiconductor chip of the type having essentially parallel first and second broad area surfaces separated a thickness dimension and bounded by side surfaces and wherein heat is generated in said chip in the vicinity of the said first broad area surface through which external power and signal connections are made, and wherein heat is principally removed through said second broad area surface;
the improvement for heat transfer efficiency comprising in combination:
positioning said chip on a thermally conductive layer on a surface of a thermally conductive plate, said plate supporting power and signal conductors with said power and signal conductors being connected through said thermally conductive layer to said chip,
positioning a thermally conductive cover member over said chip, said cover member having peripheral portions extending into continuous contact with said surface of said thermally conductive plate all around said chip forming thereby a cavity surrounding said chip, and,
filling said cavity with thermally conductive paste.

16. The improvement of claim 15 wherein there is pressure on said thermally conductive paste in said cavity achieved through at least one input port into said cavity with spring loaded stopper.

17. The improvement of claim 16 wherein at least one of said thermally conductive plate and said thermally conductive cover are of a material taken from the group of silicon material, diamond like coated material and copper-invar-copper material.

18. The improvement of claim 17 wherein said thermally conductive paste is silicon nitride powder in an oil mixture.

19. The process for fabrication of an improved heat transfer chip package comprising the steps of:
positioning, on a conductor bearing substrate, a thermally conductive plate having, first and second broad area surfaces with at least one of power and signal type conductor connecting members correlated with conductors on said substrate, said connecting members extending through said plate from said first to said second broad area surface and having bumps at said first broad area surface said bumps being operable to establish a separation of parts at said surface,
positioning a semiconductor chip part with the power and signal input broad area surface in contact with said bumps on said first broad area surface of said plate,
positioning a thermally conductive cover member over said chip, said cover member being shaped to enclose said chip in a cavity, the peripheral edges of said cover surrounding said chip being in continuous contact with said first broad surface of said plate, and,
filling said cavity with thermoconductive paste, said separation permitting said thermoconductive paste to flow between said power and signal input surface of said chip and first broad area surface of said plate and around said bumps.

20. The process of claim 19 including soldering a heat dissipation device onto said cover member.
